(19) United States
(12) Patent Application Publication
(10) Pub. No.: US 2025/0338774 A1
(43) Pub. Date: Oct. 30, 2025

(54) ACOUSTIC ISOLATOR

(71) Applicant: Texas Instruments Incorporated, Dallas, TX (US)

(72) Inventors: Peter SMEYS, San Jose, CA (US); Mohammad Hadi MOTIEIAN NAJAR, Santa Clara, CA (US); Ting-Ta YEN, San Jose, CA (US); Ahmad BAHAI, Lafayette, CA (US)

(73) Assignee: Texas Instruments Incorporated, Dallas, TX (US)

(21) Appl. No.: 19/260,702

(22) Filed: Jul. 7, 2025

Related U.S. Application Data
(62) Division of application No. 16/233,350, filed on Dec. 27, 2018, now Pat. No. 12,356,864.
(60) Provisional application No. 62/620,825, filed on Jan. 23, 2018.

(51) Int. Cl. H10N 30/88; H04R 1/40; H04R 17/00; H04R 17/02; H04R 31/00; H10N 30/20; H10N 30/30; H10N 30/85; H10N 30/87; H10N 39/00

(52) U.S. Cl. CPC H10N 30/883; H04R 1/403; H04R 17/00; H10N 30/20; H10N 30/30; H10N 30/872; H10N 39/00; H04R 17/02; H04R 31/00; H10N 30/85; H10N 30/877

(57) ABSTRACT

In one example, an integrated circuit (IC) comprises: a lead frame including first terminals and second terminals; a first transducer and a second transducer, the first transducer coupled to the first terminals, and the second transducer coupled to the second transducer; an acoustic medium coupled to the first and second transducers; and a mold compound encapsulating at least parts of the lead frame, the first and second transducers, and the acoustic medium.

### CROSS-REFERENCE TO RELATED APPLICATIONS

This application is a Division of U.S. patent application Ser. No. 16/233,350, filed Dec. 27, 2018, which claims priority to U.S. Provisional Patent Application No. 62/620,825, filed Jan. 23, 2018, entitled “Acoustic Isolator,” both of which are hereby incorporated herein by reference in its entirety.

### BACKGROUND

Many circuits include devices that electrically isolate one part of the circuit from another part of the circuit. An example includes an optocoupler. An optocoupler includes a light source (e.g., a light emitting diode) and a light sensitive device (e.g., a photo diode). An incoming signal causes the light source to illuminate and the light signal generated by the light source in turn causes an electrical signal to be generated by the light sensitive device. Accordingly, the information encoded in the incoming electrical signal is passed through the optocoupler but without a direct electrical connection. The optocoupler prevents damage to downstream circuit components that might otherwise occur in the face of an overcurrent or over-voltage condition on the input signal.

### SUMMARY

In one example, a semiconductor device includes an acoustic medium, a first acoustic transducer on the acoustic medium, a first electrode coupled to the first acoustic transducer, a second acoustic transducer on the acoustic medium, and a second electrode coupled to the second acoustic transducer. The semiconductor device also includes a semiconductor substrate to support the acoustic medium and first and second transducers. Mold compound encapsulates at least a portion of the acoustic medium, the first acoustic transducer, the second acoustic transducer, and the semiconductor substrate.

### BRIEF DESCRIPTION OF THE DRAWINGS

FIG. 1 illustrates an acoustic isolator in accordance with an example.

FIGS. 2-8 illustrate a sequence of processing operations to form an acoustic isolator in accordance with an example.

FIG. 9 illustrates an example of an acoustic isolator including acoustic transducers on opposing surfaces of an acoustic medium.

FIG. 10 illustrates an example of an acoustic isolator including acoustic transducers on the same surface of an acoustic medium.

### DETAILED DESCRIPTION

The described examples are directed to an acoustic isolator. The described acoustic isolator includes multiple acoustic transducers on an acoustic medium. The acoustic transducers may include piezoelectric materials. One acoustic transducer vibrates in response to an electrical input signal. The vibrating acoustic transducer causes an acoustic signal to be generated which then propagates through the acoustic medium to another acoustic transducer where the acoustic signal is converted back to an electrical signal. Power can be transferred acoustically through the transducer. Thus, the described acoustic isolator can be used to transfer data signals and/or power.

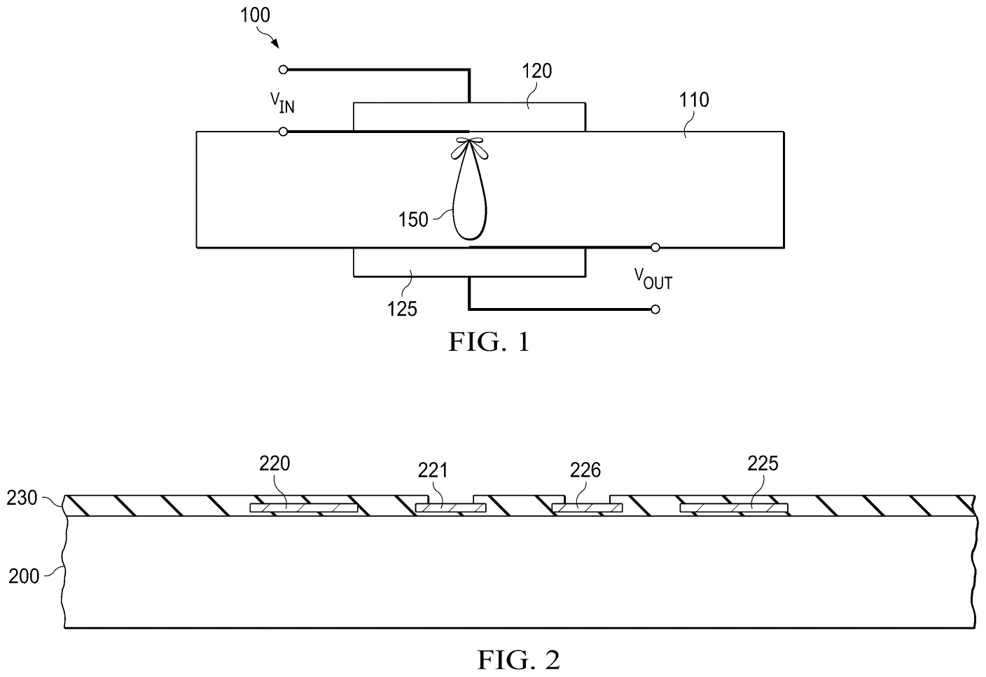

FIG. 1 shows an acoustic isolator 100 in accordance with an example. The acoustic isolator 100 includes an acoustic medium 110 and acoustic transducers 120 and 125 on the acoustic medium 110. In some embodiments, the acoustic medium 110 includes glass, silicon carbide, sapphire, silicon dioxide, diamond, silicon nitride, and quartz. Each of the acoustic transducers 120, 125 comprises a material that can be made to vibrate based on an electrical signal. In one example, each acoustic transducer 120, 125 includes a ceramic material, quartz, aluminum nitride, lead zirconate titanate, or any suitable type of piezoelectric material. The material comprising acoustic transducer 120 can be the same or different from the material comprising acoustic transducer 125. In some examples, the acoustic impedance of the acoustic medium 110 approximately matches the acoustic impedance of the acoustic transducers 120, 125.

In operation, an input electrical signal, Vin, is provided to electrical contacts connected to acoustic transducer 120. Acoustic signals 150 are generated and propagate through the acoustic medium 110 from the acoustic transducer 120 to the acoustic transducer 125. The acoustic transducer 125 converts the acoustic signal 150 to an output electrical signal, Vout which is accessible via electrical contacts connected to acoustic transducer 120. Electrical isolation is thereby provided by the acoustic isolator 100.

FIGS. 2-8 illustrate the sequence of operations to fabricate the acoustic isolator. FIG. 2 shows a semiconductor substrate (e.g., silicon) 200 on which layer 230 is formed. Layer 230 includes one or more acoustic transducers 220 and 225. An electrical contact 221 provides electrical contact to acoustic transducer 220. Similarly, electrical contact 226 provides electrical contact to acoustic transducer 225. In one example, the processing described herein is performed on a wafer level. Accordingly, multiple acoustic isolators can be performed on a single semiconductor wafer. The semiconductor substrate 200 may comprise a wafer.

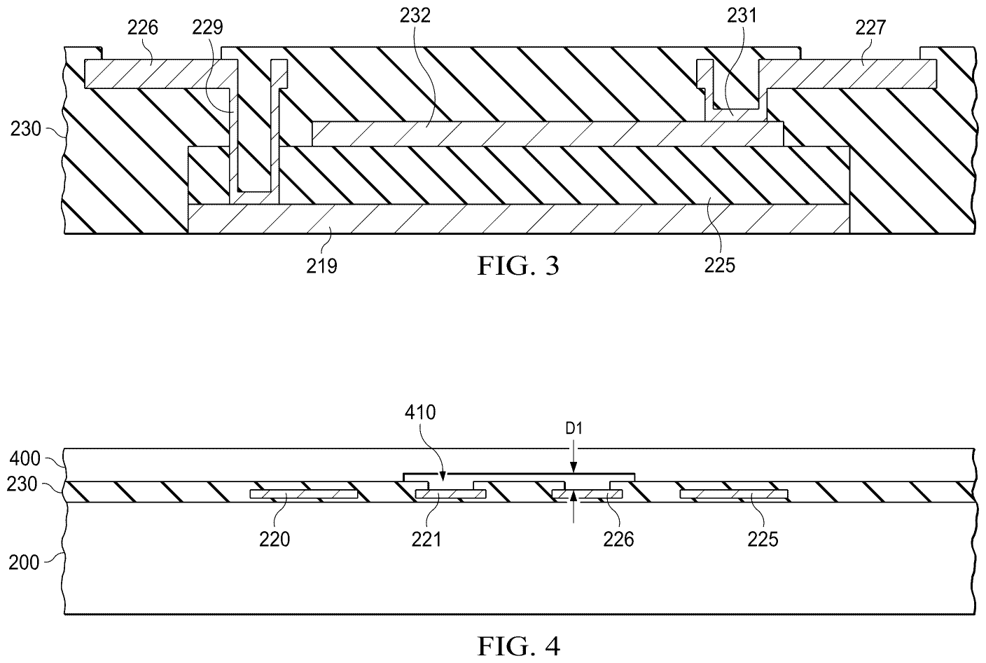

FIG. 3 illustrates a portion of layer 230 including the acoustic transducer 225 and electrical contact 226. A second electrical contact 227 also is shown in FIG. 2 (not in FIG. 1). The acoustic isolator 225 comprises opposing surfaces on which electrodes 230 and 219 are formed. In some examples, electrodes 219, 232 are made from a conductive material (e.g., molybdenum, copper, aluminum, gold, etc.). Layer 230 also comprises silicon dioxide or other suitable dielectric material. Electrode 219 is electrically coupled to electrical contact 226 via interconnect 229. Interconnect 229 comprises aluminum or other suitable conductive material. Similarly, electrode 232 is electrically coupled to electrical contact 227 via interconnect 231, which also may comprise aluminum. Electrical contacts 226 and 227 provide electrical connectivity to the acoustic transducer 225. Openings in layer 230 are formed to provide access to electrical contacts 226 and 227. The other acoustic transducers and their electrodes and electrical contacts are similarly configured.

In FIG. 4, another wafer 400 is patterned to include cavities 410 as shown and fusion bonded to layer 230. The wafer 400 may comprise glass in some examples. In some examples, the depth D1 of the cavity 410 is between 10 and 20 micrometers (microns).

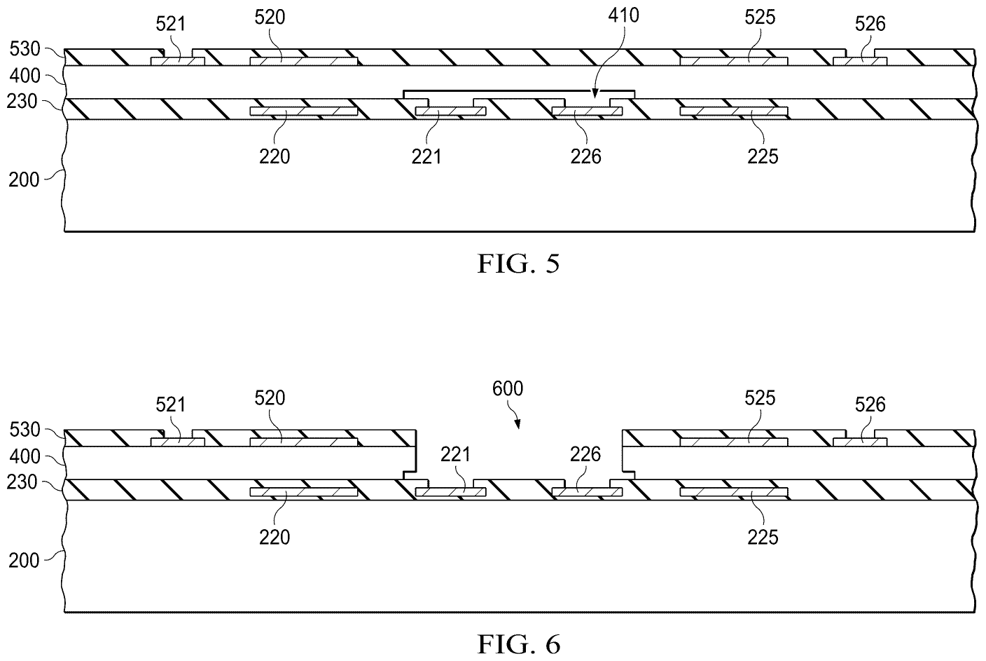

Another layer 530 is formed over wafer 400. Layer 530 also includes multiple acoustic transducers 520 and 525 as well as corresponding electrical contacts 521 and 526. The materials and construction of layer 530 can be the same or similar as layer 230. Accordingly, each acoustic transducer 520, 525 includes multiple electrical contacts, although only one contact for each transducer 520, 525 is shown in FIG. 5.

FIG. 6 illustrates that the acoustic medium is removed at 600 is formed to expose the electrical contacts 221 and 226 associated with acoustic transducers 220 and 225. In one example, the opening 600 is formed by tab dicing or etching. Tab dicing is partial dicing, which dices partially through a bonded wafer pair or multi-layer structure to expose the specific areas for different purpose such as sensing or electrical contacts

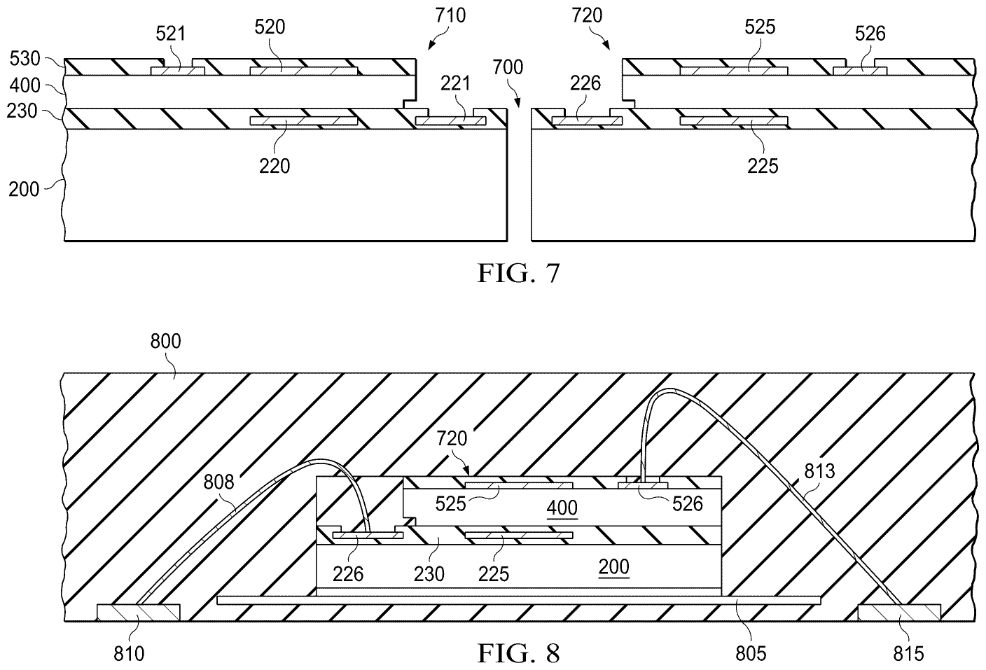

In FIG. 7, the semiconductor substrate 200 on which the structures described herein are formed is singulated into individual die, each die comprising a structure that includes at least one acoustic isolator. FIG. 7 illustrates that a cut is made at 700 to singulate the structure shown into two separate structures 710 and 720. In one example, each of structures 710 and 720 comprises a single acoustic isolator. In other examples, each singulated structure 710 and 720 comprises multiple acoustic isolators. In one particular example, each singulated structure comprises one or more integrated circuits (e.g., a processing core, a phase-lock loop, memory, input/output ports, etc.) as well as one or more acoustic isolators to provide electrical isolation for signals generated by, or to be provided to, the integrated circuit(s).

FIG. 8 shows a singulated structure attached to a leadframe 805 (or laminated substrate). Wirebonds 808 and 813 electrically connect the electrical contacts of the acoustic transducers (e.g., contacts 226 and 526 of acoustic transducers 225 and 525) to contact pads 810 and 815. Mold compound 800 then encapsulates at least a portion of the acoustic medium 400, the acoustic transducers 225 and 525, and the semiconductor substrate 200. In FIG. 8, the mold compound 800 encapsulates all of the components shown in FIG. 8 except for a surface of contact pads 810 and 815 so that external electrical connection can be made to the pads. In some examples, the acoustic isolator described herein can be fabricated as a package which attaches to a circuit board by way of a pair of conductive legs.

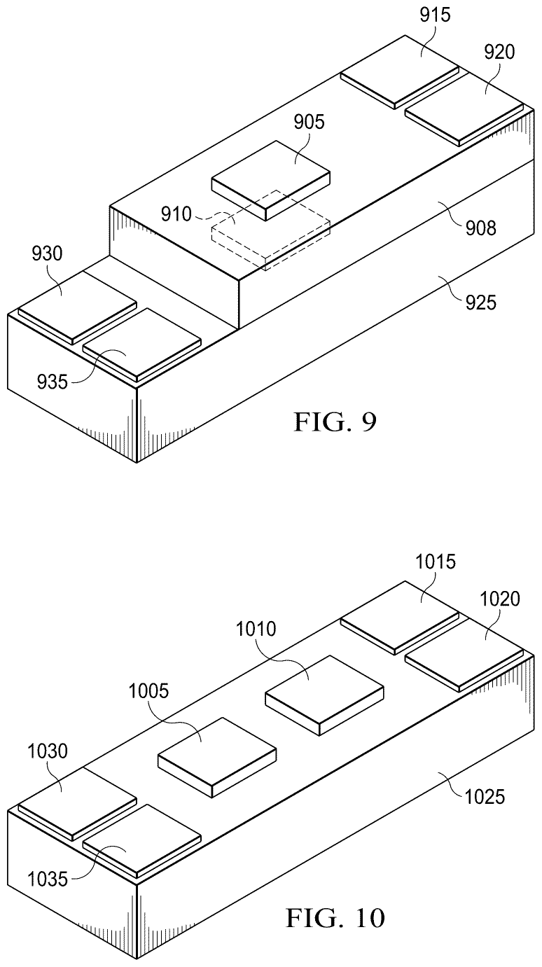

FIG. 9 shows an example (similar that of FIGS. 1-8) in which a pair of acoustic transducers 905, 910 is provided on opposing surfaces of an acoustic medium 908. Electrical contacts 915 and 920 are provided on the acoustic medium 908 as well for connection to acoustic transducer 905. Further, electrical contacts 930 and 935 are provided on the semiconductor substrate 925 for connection to acoustic transducer 910.

FIG. 10 shows an example in which a pair of acoustic transducers 1005 and 1010 is provided on the same surface of an acoustic medium 1025 (e.g., glass). Electrical contacts 1015 and 1020 are provided on the acoustic medium 1025 for connection to acoustic transducer 1005. Further, electrical contacts 1030 and 1035 are provided on the acoustic medium 1025 for connection to acoustic transducer 1010. In this configuration, the acoustic media allows two acoustic transducers to acoustically couple to each other laterally.

In the examples described herein, the direction of signal flow through the isolator is bidirectional. Accordingly, either transducer can be used to generate the acoustic signal for detection by the other transducer.

In this description, the term “couple” or “couples” means either an indirect or direct wired or wireless connection. Thus, if a first device couples to a second device, that connection may be through a direct connection or through an indirect connection via other devices and connections. The term “approximately” refers to a value that is within plus or minus 10% of another value or range of values.

Modifications are possible in the described embodiments, and other embodiments are possible, within the scope of the claims.

What is claimed is:

1. An integrated circuit (IC), comprising:
a lead frame including first terminals and second terminals;
a first transducer and a second transducer, the first transducer coupled to the first terminals, and the second transducer coupled to the second transducer;
an acoustic medium coupled to the first and second transducers; and
a mold compound encapsulating at least parts of the lead frame, the first and second transducers, and the acoustic medium.

2. The IC of claim 1, further comprising a substrate on the lead frame, and the first transducer is between the substrate and a first side of the acoustic medium, and the second transducer is on a second side of the acoustic medium opposing the first side.

3. The IC of claim 2, further comprising a first electrical contact on a surface of the substrate and a second electrical contact on the second side of the acoustic medium, the first electrical contacts coupled to the first transducer, and the second electrical contact coupled to the second transducer.

4. The IC of claim 3, wherein the first electrical contact is coupled to the first terminal via a first interconnect, and the second electrical contact is coupled to the second terminal via a second interconnect.

5. The IC of claim 4, wherein each of the first and second interconnects includes a respective bond wire.

6. The IC of claim 1, wherein the first and second transducers are on a same side of the acoustic medium.

7. The IC of claim 1, wherein the acoustic medium includes material selected from the group consisting of glass, silicon carbide, sapphire, silicon dioxide, diamond, silicon nitride, and quartz.

8. The IC of claim 1, wherein at least one of the first and second acoustic transducers includes a piezoelectric material.

9. The IC of claim 1, wherein the acoustic medium has an acoustic impedance that approximately matches an acoustic impedance of the first acoustic transducer and an acoustic impedance of the second acoustic transducer.

10. A method comprising:
coupling a first transducer and a second transducer to an acoustic medium;
coupling the first transducer to first terminals of a lead frame;
coupling the second transducer to second terminals of the lead frame; and
encapsulating at least parts of the lead frame, the first and second transducers, and the acoustic medium with a mold compound.

11. The method of claim 10, further comprising:
forming the first transducer and a first electrical contact on a substrate, the first electrical contact coupled to the first transducer;
forming a wafer on the first transducer, the wafer including a cavity over the first electrical contact;
forming the second transducer and a second electrical contact on the wafer; and
removing part of the wafer over the cavity to form the acoustic medium and expose the first electrical contact.

12. The method of claim 11, further comprising:
coupling the first electrical contact to the first terminal via a first interconnect; and
coupling the second electrical contact to the second terminal via a second interconnect.

13. The method of claim 12, wherein each of the first and second interconnects includes a respective bond wire.

14. The method of claim 10, wherein the acoustic medium includes material selected from the group consisting of glass, silicon carbide, sapphire, silicon dioxide, diamond, silicon nitride, and quartz.

15. The method of claim 10, wherein at least one of the first and second acoustic transducers includes a piezoelectric material.

16. The method of claim 10, wherein the acoustic medium has an acoustic impedance that approximately matches an acoustic impedance of the first acoustic transducer and an acoustic impedance of the second acoustic transducer.
